(19) United States
(12) Patent Application Publication
(10) Pub. No.: US 2026/0101602 A1
(43) Pub. Date: Apr. 9, 2026

(54) ISOLATION STRUCTURE HAVING LAYOUT TO INCREASE IMAGE SENSOR PERFORMANCE

(71) Applicant: Taiwan Semiconductor Manufacturing Company, Ltd., Hsinchu (TW)

(72) Inventors: Ting-Jung Chen, Kaohsiung City (TW); Yi-Jie Tsai, Tainan City (TW); Ming-Yu Kuo, Tainan City (TW); Tsung-Yu Lee, Tainan City (TW); Chih Cheng Shih, Kaohsiung City (TW)

(21) Appl. No.: 19/053,550

(22) Filed: Feb. 14, 2025

Related U.S. Application Data
(60) Provisional application No. 63/703,347, filed on Oct. 4, 2024.

(51) Int. Cl. H10F 39/00; H10F 39/18

(52) U.S. Cl. CPC H10F 39/807; H10F 39/014; H10F 39/18; H10F 39/812; H10F 39/813

(57) ABSTRACT

Various embodiments of the present disclosure are directed towards an integrated chip (IC). The IC includes a first pixel region comprising a first photodetector in a substrate. A second pixel region comprising a second photodetector is in the substrate and adjacent to the first pixel region. An isolation structure in the substrate and comprising a first isolation structure element between the first and second pixel regions. In top view the first isolation structure element has a first pair of opposing straight sidewall segments and a first pair of opposing curved sidewall segments adjacent to the first pair of opposing straight sidewall segments. A first distance between the first pair of opposing straight sidewall segments is greater than a second distance between the first pair of opposing curved sidewall segments.

### REFERENCE TO RELATED APPLICATION

This Application claims the benefit of U.S. Provisional Application number 63/703,347, filed on Oct. 4, 2024, the contents of which are hereby incorporated by reference in their entirety.

### BACKGROUND

Many modern-day electronic devices (e.g., digital cameras, optical imaging devices, etc.) comprise image sensors. An image sensor comprises an array of pixel regions, and each pixel region contains a photodiode configured to capture optical signals (e.g., light) and convert it to digital data (e.g., a digital image). Complementary metal-oxide-semiconductor (CMOS) image sensors are often used over charge-coupled device (CCD) image sensors because of their many advantages, such as lower power consumption, faster data processing, and lower manufacturing costs.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A-1C illustrate various views of some embodiments of an image sensor comprising a plurality of pixel regions and an isolation structure having a layout configured to increase performance of the image sensor.

FIGS. 2A-2C illustrate various views of some other embodiments of the image sensor of FIGS. 1A-1C.

FIG. 3 illustrates a top view of some other embodiments of the image sensor of FIG. 2A.

FIG. 4 illustrates a cross-sectional view of some embodiments of the image sensor of FIG. 3 taken along the line A-A′ of FIG. 3.

FIG. 5 illustrates a top view of some other embodiments of the image sensor of FIGS. 1A-1C.

FIG. 6 illustrates a cross-sectional view of some embodiments of the image sensor of FIG. 5 taken along the line A-A′ of FIG. 5.

FIGS. 7-15 illustrate various views of some embodiments of a method of forming an image sensor comprising a plurality of pixel regions and an isolation structure with a layout configured to increase performance of the image sensor.

FIG. 16 illustrates a flowchart according to some embodiments of a method for forming an image sensor comprising a plurality of pixel regions and an isolation structure with a layout configured to increase performance of the image sensor.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An integrated chip (IC) may comprise an image sensor including a plurality of pixel regions arranged in an array. Each of the pixel regions comprises a photodetector (e.g., a photodiode) disposed within a substrate and configured to convert incident radiation (e.g., visible light) to charge carriers. The converted charge carriers may be transferred to a floating diffusion node in the substrate to facilitate digital readout of the incident radiation. Multiple pixel regions may share one floating diffusion node, where the floating diffusion node is arranged at a crossroad of neighboring pixel regions. For example, the image sensor comprises a plurality of a pixel sensor units that may each have a two-by-two shared pixel layout, where a floating diffusion node is disposed at a middle region of four adjacent photodetectors.

An isolation structure is disposed in the substrate between neighboring pixel regions and is configured to mitigate optical and electrical cross-talk between the pixel regions. Forming the isolation structure may include performing an etch process into a back-side surface of the substrate to form a trench extending into the substrate between the pixel regions and depositing the isolation structure in the trench. In a top view, the isolation structure has a grid layout, where sidewalls of the isolation structure demarcate an area of each pixel region.

In an effort to increase a sensing area of the image sensor and increase device density, a width of the trench between adjacent pixel regions is decreased. As a result, an area for the photodetector of each pixel region is increased and spacing between neighboring pixel regions is decreased. However, decreasing the width of the trench may increase dark current and/or white pixels in the image sensor. For example, the isolation structure may comprise a first isolation structure segment disposed in a first trench segment of the trench that is aligned with the floating diffusion, and a second isolation structure segment disposed in a second trench segment of the trench disposed around the pixel regions. The first isolation structure segment may have a first depth and the second isolation structure may have a second depth greater than the first depth. Decreasing the width of the first trench segment between adjacent pixel regions that the first isolation structure segment is disposed in may result in a variation of etchant flow (e.g., due to etch loading) during the etch process at the crossroad of neighboring pixel regions for each pixel sensor unit. As a result, the substrate may be over etched in a region aligned with a center of each floating diffusion node while leaving elevated portions of the substrate at the crossroad of neighboring pixel regions that provide a path for charge carriers (e.g., electrons) to flow, thereby increasing leakage current. Further, polymer may be utilized during the etch process to mitigate damage to sidewalls of the substrate. However, as a width of the trench is decreased, polymer may accumulate in regions of deeper segments of the second trench segment at a crossroad between neighboring pixel sensor units. As a result, the substrate may comprise a plurality of protrusions around the deeper segments of the trench, thereby providing additional paths for charge carriers to flow between pixel regions and further increasing leakage current. Accordingly, dark current and/or white pixel issues across the image sensor may be increased, thereby decreasing an overall performance of the IC.

In various embodiments, the present application is directed towards an IC including an image sensor, the image sensor comprises an isolation structure having a layout configured to improve a performance of the image sensor. The image sensor comprises a plurality of pixel sensor units arranged on a substrate. Each pixel sensor unit may include a plurality of pixel regions and a floating diffusion node at a crossroad of the plurality of pixel regions. The isolation structure is disposed in a trench defined by sidewalls of the substrate and comprises a first isolation structure segment having a first depth and a second isolation structure segment having a second depth greater than the first depth. The first isolation structure segment is arranged at the crossroad of the plurality of pixel regions of an individual pixel sensor unit. The first isolation structure segment comprises multiple curved sidewall segments facing one another at the crossroad and straight sidewall segments connected to the curved sidewall segments. A first lateral distance between opposing straight sidewalls in the multiple straight sidewall segments is greater than a second lateral distance directly between adjacent curved sidewall segments in the multiple curved sidewall segments. By virtue of the first isolation structure having the curved sidewall segments and the straight sidewall segments, etchants utilized during the etching process used to form the trench in the substrate may more uniformly flow at the crossroad of the plurality of pixel regions. Thus, issues due to etch loading at the crossroad of the plurality of pixel regions of each pixel sensor unit are mitigated or prevented, thereby decreasing leakage current in the image sensor. Further, the second isolation structure segment has multiple curved sidewall segments facing one another at crossroads of the plurality of pixel regions. A layout of the curved sidewall segments of the second isolation structure segment is configured to mitigate an accumulation of polymer at the crossroads of the plurality of pixel regions during the etching process. As a result, leakage current in the image sensor is further reduced, thereby improving an overall performance of the image sensor.

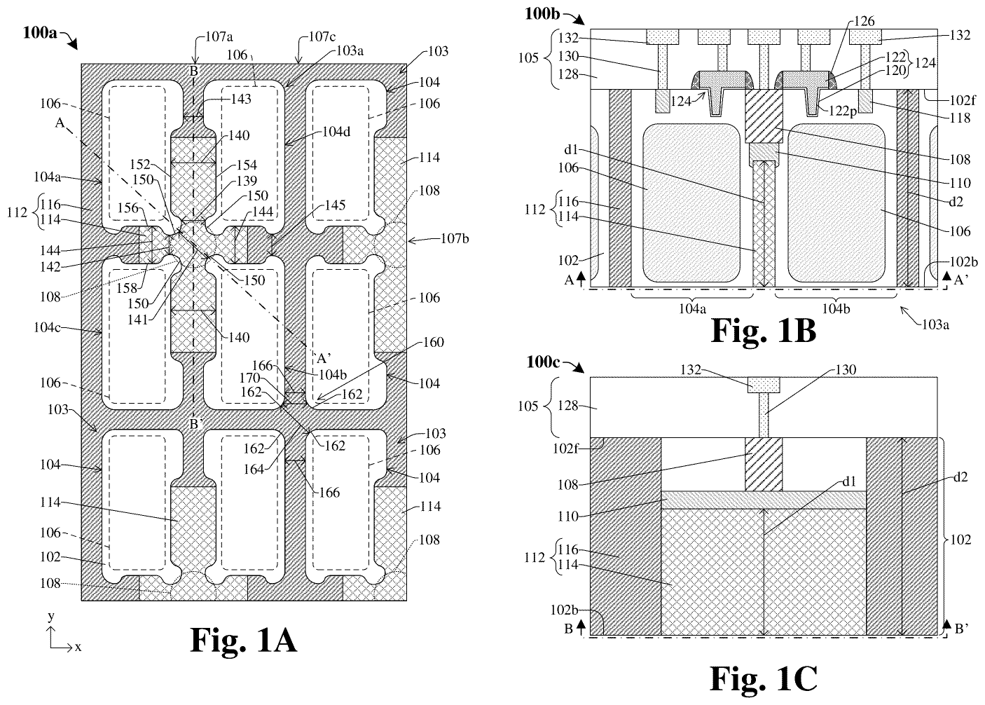

FIGS. 1A-1C illustrate various views 100a-100c of some embodiments of an image sensor comprising a plurality of pixel regions 104 and an isolation structure 112 including first isolation structure segments 114 and a second isolation structure segment 116 having a layout configured to increase performance of the image sensor. FIG. 1A illustrates a top view 100a of the image sensor from a back-side surface 102b of a substrate 102. FIG. 1B illustrates a cross-sectional view 100b taken along line A-A′ of the top view 100a of FIG. 1A. FIG. 1C illustrates a cross-sectional view 100c taken along B-B′ of the top view 100a of FIG. 1A.

As shown in the top view 100a of FIG. 1A, the image sensor comprises a plurality of pixel sensor units 103 arranged on a substrate 102. In some embodiments, the pixel sensor units 103 respectively have a shared pixel layout structure and include a plurality of pixel regions 104 and a floating diffusion node 108 disposed at a crossroad of the plurality of pixel regions 104. The plurality of pixel regions 104 respectively comprise an individual photodetector 106 disposed in the substrate 102. For example, the plurality of pixel sensor units 103 comprises a first pixel sensor unit 103a having a first plurality of pixel regions 104a-d. The first plurality of pixel regions 104a-d includes a first pixel region 104a, a second pixel region 104b, a third pixel region 104c, and a fourth pixel region 104d. The second pixel region 104b is diagonally opposite the first pixel region 104a and the third pixel region 104c is diagonally opposite the fourth pixel region 104d. It will be appreciated that the floating diffusion nodes 108 and the photodetectors 106 are represented in phantom in the top view 100a of FIG. 1A for ease of illustration.

The substrate 102 may, for example, be or comprise silicon, CMOS bulk, silicon-germanium, a silicon-on-insulator (SOI), or some other suitable semiconductor material. The substrate 102 may have a first doping type (e.g., p-type). In some embodiments, the photodetectors 106 are or comprise a doped region in the substrate 102 having a second doping type (e.g., n-type) opposite the first doping type (e.g., p-type). In various embodiments, the first doping type is p-type and the second doping type is n-type, or vice versa. The floating diffusion nodes 108 have the second doping type (e.g., n-type) and are each arranged at a center and/or a crossroad of a corresponding pixel sensor unit 103.

The isolation structure 112 is disposed within the substrate 102 between adjacent pixel regions 104. The isolation structure 112 is configured to increase electrical and optical isolation between the pixel regions 104 across the image sensor. In some embodiments, the substrate 102 comprises sidewalls defining a trench arranged in the substrate 102 between the adjacent pixel regions 104, where the isolation structure 112 is disposed in the trench. The isolation structure 112 comprises a plurality of first isolation structure segments 114 and a second isolation structure segment 116. The first isolation structure segments 114 are arranged at a corresponding crossroad of the plurality of pixel regions 104 of each pixel sensor unit 103. The second isolation structure segment 116 is disposed on opposing sides of each of the first isolation structure segments 114 and is arranged between adjacent pixel regions 104. In some embodiments, the second isolation structure segment 116 continuously laterally extends around an outer perimeter of each pixel sensor unit in the plurality of pixel sensor units 103. In various embodiments, the first isolation structure segments 114 have a first depth (e.g., d1 of FIG. 1B) and the second isolation structure segment 116 has a second depth (e.g., d2 of FIG. 1B) greater than the first depth. In some embodiments, the isolation structure 112 may be referred to as a dual deep trench isolation (DTI) structure, the first isolation structure segments 114 may be referred to as partial depth trench isolation (PDTI) structures or PDTI segments, and the second isolation structure segment 116 may be referred to as a full depth trench isolation (FDTI) structure or FDTI segments.

As seen at the crossroad of the first plurality of pixel regions 104a-d of the first pixel sensor unit 103a, the substrate 102 comprises curved sidewall segments that protrude from a corresponding pixel region in the first plurality of pixel regions 104a-d towards the floating diffusion node 108. The first isolation structure segment 114 has a plurality of curved sidewall segments 150 that conform to the curved sidewall segments of the substrate 102. A shape, location, and/or size of the plurality of curved sidewall segments 150 of the first isolation structure segment 114 are configured to reduce a distance between diagonally separated pixel regions in the first plurality of pixel regions 104a-d in a region aligned with the floating diffusion node 108. For example, the plurality of curved sidewall segments 150 are configured to reduce a first diagonal distance 141 between the first pixel region 104a and the second pixel region 104b. Further, the first isolation structure segment 114 comprises a first pair of opposing straight sidewall segments 152, 154 elongated in a first direction (e.g., along the y-axis) and separated from one another by a first lateral distance 140 greater than a lateral distance 139 between directly adjacent curved sidewall segments in the plurality of curved sidewall segments 150. The first isolation structure segment 114 comprises a second pair of opposing straight sidewall segments 156, 158 elongated in a second direction (e.g., along the x-axis) and separated from one another by a second lateral distance 144 greater than a lateral distance 142 between another directly adjacent curved sidewall segments in the plurality of curved sidewall segments 150. In some embodiments, the first direction (e.g., along the y-axis) is orthogonal to or substantially orthogonal to the second direction (e.g., along the x-axis).

By reducing the first diagonal distance 141 and increasing the first and second lateral distances 140, 144 compared to another isolation structure (not shown) having sidewalls defining a simple rectangular shape when viewed in top view over an individual pixel region, one or more etchants utilized to form the trench in the substrate 102 may more uniformly flow at the crossroad of the first plurality of pixel regions 104a-d. As a result, etching of the substrate 102 at the crossroad of the plurality of pixel regions 104 of each of the pixel sensor units 103 across the image sensor may be more uniform and/or more easily controlled. This, in part, mitigates one or more current leakage paths in the substrate 102 between the pixel regions 104, thereby reducing dark current and/or white pixel issues and improving a dynamic range of the image sensor.

As seen at a crossroad 160 of the plurality of pixel sensor units 103, the substrate 102 comprises other curved sidewall segments that protrude from a corresponding pixel region of the plurality of pixel sensor units 103. The second isolation structure segment 116 comprises curved sidewall segments 162 that conform to the other curved sidewall segments of the substrate 102. A shape, location, and/or size of the curved sidewall segments 162 of the second isolation structure segment 116 are configured to increase a distance between diagonally separated pixel regions in the plurality of pixel sensor units 103. For example, the plurality of curved sidewall segments 162 of the second isolation structure segment 116 is configured to increase a second diagonal distance 164 between the second pixel region 104b and a diagonally separated pixel region 104 of another pixel sensor unit 103. By increasing the second diagonal distance 164, a polymer utilized during the etch process used to form the trench in the substrate 102 is less likely to accumulate at the crossroad 160 of the plurality of pixel sensor units 103. Accordingly, the substrate 102 may be more uniformly etched at the crossroad 160 of the plurality of pixel sensor units 103, thereby further reducing current leakage paths in the substrate 102 between the pixel regions 104. This further reduces dark current and/or white pixel issues and further improves the dynamic range of the image sensor. Thus, by virtue of the isolation structure 112 having the layout as configured and/or illustrated in the top view 100a of FIG. 1A, feature sizes of the pixel sensor units 103 may be scaled down while mitigating leakage current in the image sensor, thereby increasing an overall performance of the image sensor.

In various embodiments, the plurality of pixel regions 104 are arranged in an array comprising a plurality of columns and a plurality of rows. Inner sidewalls of the isolation structure 112 demarcate and/or define outer perimeters of each of the pixel regions 104. The trench of the substrate 102 comprises a first elongated trench segment 107a extending along the first direction (e.g., along the y-axis) between a first column and a second column of the array of pixel regions 104. A width of the first isolation structure segment 114 in the first elongated trench segment 107a and on opposite sides of the floating diffusion node 108 is equal to the first lateral distance 140. In various embodiments, the first lateral distance 140 is greater than the lateral distance 139 between curved sidewall segments 150 of the first isolation structure segment 114 in the first elongated trench segment 107a. In further embodiments, the first lateral distance 140 is greater than a lateral distance 143 between opposing sidewall segments of the second isolation structure segment 116 in the first elongated trench segment 107a. In some embodiments, the first lateral distance 140 is within a range of about 80 to 240 nanometers (nm), within a range of about 240 to 400 nm, within a range of about 80 to 400 nm, or some other suitable value.

The trench of the substrate 102 comprises a second elongated trench segment 107b extending along the second direction (e.g., along the x-axis) between a first row and a second row of the array of pixel regions 104. A width of the first isolation structure segment 114 in the second elongated trench segment 107b and on opposite sides of the floating diffusion node 108 is equal to the second lateral distance 144. In various embodiments, the second lateral distance 144 is greater than the lateral distance 142 between curved sidewall segment 150 of the first isolation structure segment 114 in the second elongated trench segment 107b and is greater than a lateral distance 145 between opposing sidewall segments of the second isolation structure segment 116 in the second elongated trench segment 107b. In some embodiments, the second lateral distance 144 is within a range of about 80 to 240 nm, within a range of about 240 to 400 nm, within a range of about 80 to 400 nm, or some other suitable value. In further embodiments, the first lateral distance 140 is greater than the second lateral distance 144, which may facilitate reducing issues related to etch loading while increasing a sensing region of the pixel regions 104, thereby increasing a full well capacity of the photodetectors 106. In yet further embodiments, the first lateral distance 140 is equal to the second lateral distance 144, which may facilitate reducing issues related to etch loading while decreasing design complexity.

In various embodiments, the first diagonal distance 141 between diagonally separated pairs of curved sidewall segments in the first plurality of curved sidewall segments 150 is within a range of about 100 to 250 nm, within a range of about 250 to 400 nm, within a range of about 100 to 400 nm, or some other suitable value. In some embodiments, the first plurality of curved sidewall segments 150 are configured to reduce the first diagonal distance 141, which mitigates etching variation at the crossroad of the first plurality of pixel regions 104a-d and increases a sensing area of the pixel regions 104, thereby improving etching control and increasing an overall performance of the image sensor. In various embodiments, the first diagonal distance 141 may be greater than the first lateral distance 140 and/or greater than the second lateral distance 144. This, in part, may facilitate increasing etching control at the crossroad of the first plurality of pixel regions 104a-d while ensuring the first isolation structure segment is sufficiently wide to have good structural integrity and reduce damage (e.g., delamination and/or cracking) to the isolation structure 112.

The trench of the substrate 102 comprises a third elongated trench segment 107c extending along the first direction (e.g., along the y-axis) between the second column and a third column of the array of pixel regions 104. In some embodiments, a width of the second isolation structure segment 116 in the third elongated trench segment 107c and on opposite sides of the crossroad 160 of the plurality of pixel sensor units 103 is equal to the third lateral distance 166. In some embodiments, the third lateral distance 166 is less than a distance 170 between the second plurality of curved sidewall segments 162 of the second isolation structure segment 116 along the third elongated trench segment 107c. This, in part, may facilitate increasing the second diagonal distance 164 between diagonally separated pixel regions 104 along the third elongated trench segment 107c. As a result, etchants may more uniformly flow at the crossroad 160 and a polymer utilized during the etch process used to form the trench in the substrate 102 is less likely to accumulate at crossroads of pixel regions 104 along the third elongated trench segment 107c, thereby further increasing etching uniformity across the substrate 102. Accordingly, current leakage paths in the substrate 102 between pixel regions 104 may be further reduced, thereby further reducing current leakage across the image sensor and further increasing an overall performance of the image sensor.

The second diagonal distance 164 may, for example, be within a range of about 120 to 200 nm, within a range of about 200 to 480 nm, within a range of about 120 to 480 nm, or some other suitable value. In some embodiments, the second diagonal distance 164 is greater than the first diagonal distance 141. By virtue of the second isolation structure segment 116 having a greater depth than that of the first isolation structure segment 114, the polymer utilized during the etch process may be more prone to accumulating at the deeper depth of the second isolation structure segment 116 by the crossroad 160. Thus, in some embodiments, the second diagonal distance 164 being greater than the first diagonal distance 141 mitigates etching variation near the floating diffusion node and mitigates a buildup of polymer at the crossroad 160 during the etching process while maximizing and/or increasing sensing areas of the pixel regions 104. In further embodiments, the third lateral distance 166 is less than the first lateral distance 140 and/or the second lateral distance 144. In yet further embodiments, shapes and/or sizes of the curved sidewall segments 150 of the first isolation structure segment 114 are different from shapes and/or sizes of the curved sidewall segments 162 of the second isolation structure segment 116.

As illustrated in the cross-sectional view 100b and 100c of FIGS. 1B and 1C taken respectively along lines A-A′ and B-B′ in FIG. 1A, a plurality of transfer gate structures 124 are disposed on and/or in the substrate 102. The transfer gate structures 124 are aligned with a corresponding photodetector 106 and are adjacent to the floating diffusion node 108. The transfer gate structures 124 comprise a gate dielectric layer 120 and a gate electrode 122. The gate dielectric layer 120 is arranged between the gate electrode 122 and the substrate 102. Further, the transfer gate structures 124 comprise a protrusion 122p extending into the substrate 102 and over a corresponding photodetector 106. A sidewall spacer 126 is arranged on opposing sidewalls of the gate dielectric layer 120 and opposing sidewalls of the gate electrode 122.

The photodetectors 106 are configured to absorb incident radiation (e.g., photons) and generate respective electrical signals corresponding to the incident radiation. For example, the photodetectors 106 may generate electron-hole pairs from the incident radiation. The transfer gate structures 124 are configured to control current flow between the floating diffusion node 108 and corresponding photodetectors 106. For example, the transfer gate structures 124 are configured to selectively form a conductive channel in the substrate 102 between the floating diffusion node 108 and adjacent photodetectors 106 to transfer accumulated charge in the photodetectors 106 to the floating diffusion node 108. A well region 110 is arranged in the substrate 102 under the floating diffusion node 108. The well region 110 is arranged between the floating diffusion node 108 and the first isolation structure segment 114. The well region 110 has the first doping type (e.g., p-type) and is configured to increase electrical isolation between the pixel regions 104. In some embodiments, when viewed in top view, the well region 110 has a same layout as the first isolation structure segment 114.

A doped contact region 118 is arranged in the substrate 102 of each pixel region 104. The doped contact region 118 comprises the first doping type (e.g., p-type) and may have a doping concentration higher than that of the well region 110. In various embodiments, the doped contact region 118 may be configured to electrically couple a bulk of the substrate 102 of each of the pixel regions 104 to a reference voltage (e.g., to ground). The doped contact region 118 may, for example, be referred to as a reference voltage node or a ground node.

In some embodiments, an interconnect structure 105 overlies a front-side surface 102f of the substrate 102. The interconnect structure 105 comprises a dielectric structure 128 and a plurality of conductive vias 130 and a plurality of conductive wires 132 arranged in the dielectric structure 128. The plurality of conductive vias and wires 130, 132 are configured to facilitate readout of the photodetectors 106.

The isolation structure 112 continuously vertically extends into a back-side surface 102b of the substrate 102. The first isolation structure segment 114 has a first depth d1 defined from the back-side surface 102b to a first point above the back-side surface 102b. The second isolation structure segment 116 has a second depth d2 defined from the back-side surface 102b to a second point above the first point. In various embodiments, the first depth d1 is less than the second depth d2. In some embodiments, the second depth d2 is equal to a height of the substrate 102. The second isolation structure segment 116 having the second depth d2, that is greater than the first depth d1, facilitates increasing optical and/or electrical isolation between adjacent pixel regions 104. Further, the first isolation structure segment 114 having the first depth d1, that is less than the second depth d2, mitigates damage to the floating diffusion node 108 during fabrication of the image sensor while providing optical and/or electrical isolation between adjacent pixel regions 104.

In some embodiments, the isolation structure 112 may, for example, be or comprise silicon dioxide, silicon carbide, silicon nitride, aluminum oxide, hafnium oxide, some other suitable material, or any combination of the foregoing. Further, it will be appreciated that while the first isolation structure segment 114 and the second isolation structure segment 116 have different hashing, they may both comprise a same material and/or be part of a same structure. In some embodiments, the different hashing of the first and second isolation structure segments 114, 116 is for ease of illustration. In further embodiments, the isolation structure 112 may comprise one or more liner layers (not shown) lining the trench of the substrate 102 and one more trench fill materials (not shown) on the one or more liner layers. The one or more liner layers may, for example, be or comprise polysilicon, a dielectric material (e.g., silicon dioxide, aluminum oxide, hafnium oxide, etc.), a conductive material (e.g., titanium nitride, tantalum nitride), etc.), or the like. The one or more trench fill materials may, for example, be or comprise a dielectric material (e.g., silicon dioxide, silicon carbide, silicon carbide, aluminum oxide, hafnium oxide, etc.), a conductive material (e.g., aluminum, tungsten, titanium, or some other suitable metal), some other material, or any combination of the foregoing.

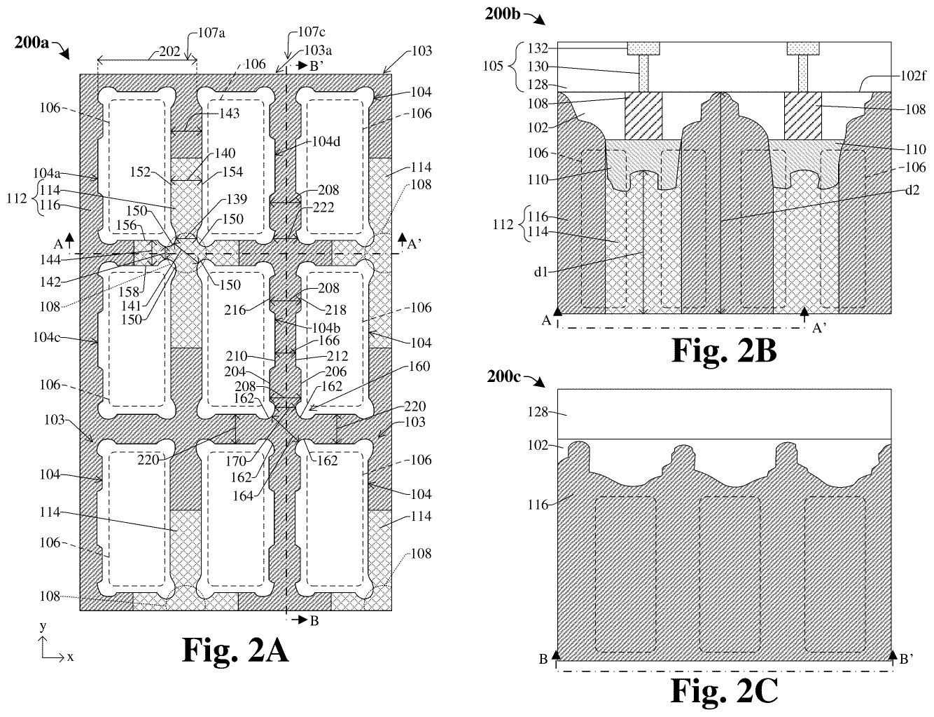

FIG. 2A illustrates a top view 200a of some other embodiments of the image sensor of FIGS. 1A-1C.

In some embodiments, the lateral distance 142 between opposing sidewalls of the second isolation structure segment 116 in the first elongated trench segment 107a may be equal to the first lateral distance 140. Further, a width of the second isolation structure segment 116 along the third elongated trench segment 107c may vary along an elongated side of each of the pixel regions 104. For example, as seen at an elongated side of the second pixel region 104b, the second isolation structure segment 116 has first opposing straight sidewall segments 204, 206 separated from one another by a fourth lateral distance 208, second opposing straight sidewall segments 210, 212 separated from one another by the third lateral distance 166, and third opposing straight sidewall segments 216, 218 separated from one another by the fourth lateral distance 208. In various embodiments, the fourth lateral distance 208 is greater than the third lateral distance 166 and is greater than the distance 170. Further, the second isolation structure segment 116 has opposing sidewalls on opposite sides of the crossroad 160 along the second direction (e.g., along the x-axis) that are separated from one another by a fifth lateral distance 220. The fifth lateral distance 220 is greater than the distance 170 and/or the third lateral distance 166.

By virtue of the second isolation structure segment 116 having the varying width across the third elongated trench segment 107c, etchants may more uniformly flow while forming the trench in the substrate 102 that defines the width of the second isolation structure segment 116 while increasing sensing areas of the pixel regions 104. For example, the fourth lateral distance 208 being greater than the distance 170 increases etching uniformity at the crossroad 160, thereby decreasing an accumulation of polymer at the crossroad 160. Further, the third lateral distance 166 being less than the fourth lateral distance 208 and being arranged at a middle region of the elongated side of the second pixel region 104b increases the sensing area of the second pixel region 104b. Thus, the second isolation structure segment 116 having the layout as illustrated and/or described in FIG. 2A further decreases leakage current in the image sensor.

In some embodiments, the fourth lateral distance 208 and the fifth lateral distance 220 may each be within a range of about 80 to 240 nm, within a range of about 240 to 400 nm, within a range of about 80 to 400 nm, or some other suitable value. In further embodiments, the fourth lateral distance 208 and the fifth lateral distance 220 are each less than the second diagonal distance 164. Further, the plurality of pixel regions 104 are arranged in an array with a pitch 202, where the pitch 202 is defined as a distance between the outer corner of an individual pixel region and a corresponding outer corner of an adjacent pixel region. In various embodiments, the pitch 202 is within a range of about 200 to 500 nm, within a range of about 500 to 800 nm, within a range of about 200 to 800 nm, or some other suitable value. By virtue of the isolation structure 112 having the layout as illustrated and/or described in FIG. 2A, the pitch 202 of the plurality of pixel regions 104 may be scaled down while mitigating leakage current across the image sensor. Further, the layout of the isolation structure 112 increases areas (e.g., sensing areas) of the pixel regions 104, thereby increasing a full well capacity of the photodetectors 106.

In various embodiments, a distance 222 between opposing curved sidewall segments of the second isolation structure segment 116 at a region laterally offset from the curved sidewall segments 150 is greater than the lateral distance 139. In further embodiments, the distance 222 is greater than the distance 170 at the crossroad 160 and is less than the fourth lateral distance 208.

It will be appreciated that while describing the layout of the isolation structure 112 in FIGS. 1A and 2B, discussions are directed towards sidewall segments and distances between sidewall segments of the isolation structure 112, these distances and/or layout of sidewall segments also applies to sidewalls of the substrate 102 defining the trench the isolation structure 112 is disposed in. The substrate 102 comprises sidewall segments that conform to the sidewall segments of the isolation structure 112. For example, the substrate 102 comprises first curved sidewall segments that conform to shapes and/or sizes of the plurality of curved sidewall segments 150, first opposing straight sidewall segments that conform to the first opposing straight sidewall segments 204, 206, and so on.

FIG. 2B illustrates a cross-sectional view 200b of some embodiments of the image sensor of FIG. 2A taken along the line A-A′ of FIG. 2A. In some embodiments, the substrate 102 comprises protrusions under a corresponding floating diffusion node 108 and extending in a direction away from the front-side surface 102f of the substrate 102. In various embodiments, the first depth d1 of the first isolation structure segment 114 is less than a height of the substrate 102 that is defined between the front-side surface 102f of the substrate 102 and the back-side surface (102b of FIG. 1B) of the substrate 102. The first depth d1 may, for example be about 0.35 micrometers (μm), 0.4 μm, within a rang of about 0.25 to 1.5 μm, or some other suitable value. In further embodiments, the second depth d2 of the second isolation structure segment 116 may, for example, be about 3.6 μm, about 3.8μm, within a range of about 3 to 3.8 μm, or some other suitable value. In various embodiments, the second depth d2 is equal to the height of the substrate 102. In yet further embodiments, the second depth d2 is greater than the height of the substrate 102.

FIG. 2C illustrates a cross-sectional view 200c of some embodiments of the image sensor of FIG. 2A taken along the line B-B′ of FIG. 2A. In various embodiments, a depth of the second isolation structure segment 116 may be less along a length of a corresponding pixel region (104 of FIG. 2A) and greater at crossroads of the pixel regions (104 of FIG. 2A).

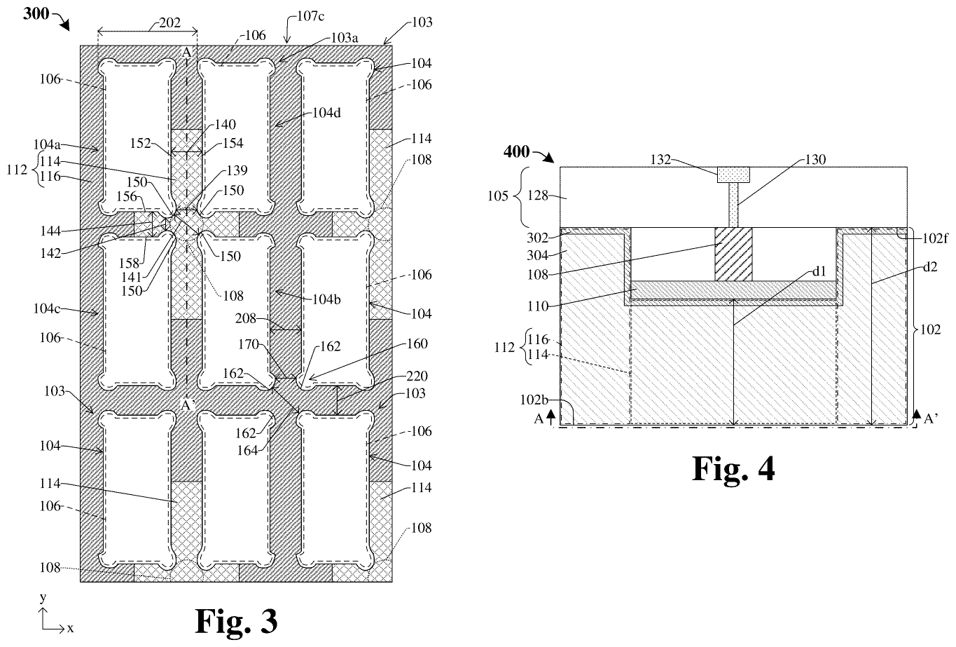

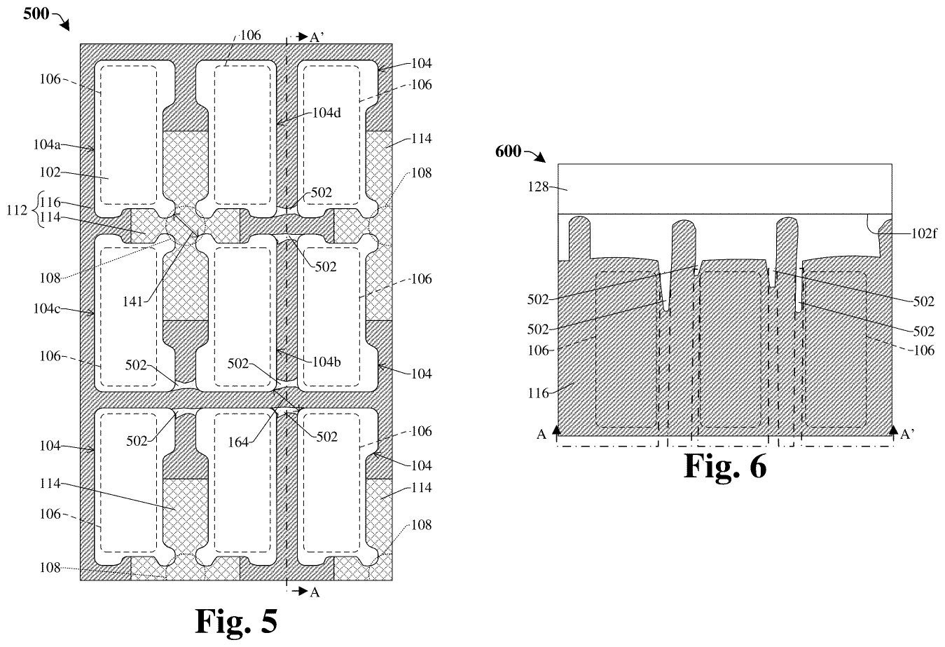

FIG. 3 illustrates a top view 300 of some other embodiments of the image sensor of FIG. 2A.

In some embodiments, the second isolation structure segment 116 has opposing sidewalls along the third elongated trench segment 107c that are arranged along corresponding elongated sides of the pixel regions 104 and separated from one another by the fourth lateral distance 208. Further, the doped region of each photodetector 106 in the substrate 102 conforms to a shape and/or layout of a corresponding pixel region 104. In various embodiments, the shapes and/or layouts of the photodetectors 106 may be defined by an ion implant mask during fabrication of the image sensor and conform to the layout of the isolation structure 112. By virtue of the photodetectors 106 conforming to a shape and/or layout of the corresponding pixel region 104, a full well capacity of each of the photodetectors 106 is increased. Further, it will be appreciated that while FIG. 3 illustrates the photodetectors having a shape and/or layout that conforms to the shape and/or layout of a corresponding pixel region 104, the photodetectors of any one of FIGS. 1A, 2A, or 5 may have a shape and/or layout that corresponding to the corresponding pixel regions in FIGS. 1A, 2A, or 5.

FIG. 4 illustrates a cross-sectional view 400 of some alternative embodiments of the image sensor of FIG. 3, where the isolation structure 112 comprises a liner layer 302 and a trench fill material 304. In some embodiments, the cross-sectional view 400 of FIG. 4 is taken along the line A-A′ of FIG. 3.

In various embodiments, the first isolation structure segment 114 and the second isolation structure segment 116 comprise segments of the liner layer 302 and the trench fill material 304. It will be appreciated that the first isolation structure segment 114 and the second isolation structure segment 116 are represented in phantom in the cross-sectional view 400 of FIG. 4. The liner layer 302 may, for example, be or comprise polysilicon, a dielectric material (e.g., silicon dioxide, aluminum oxide, hafnium oxide, etc.), a conductive material (e.g., titanium nitride, tantalum nitride), etc.), or the like. In various embodiments, the liner layer 302 may comprise a first liner layer (not shown) and a second liner layer (not shown), where the first liner layer is disposed between the substrate 102 and the second liner layer. In various embodiments, the first liner layer may, for example, be or comprise polysilicon, silicon dioxide, aluminum oxide, hafnium oxide, or the like and the second liner layer may comprise titanium nitride, tantalum nitride, or the like. The trench fill material 304 may, for example, be or comprise a dielectric material (e.g., silicon dioxide, silicon carbide, silicon carbide, aluminum oxide, hafnium oxide, etc.), a conductive material (e.g., aluminum, tungsten, titanium, or some other suitable metal), some other material, or any combination of the foregoing.

FIGS. 5 and 6 illustrates a top view 500 and a cross-sectional view 600 of some alternative embodiments of the image sensor of FIG. 1A, where the substrate 102 may comprise a plurality of pillar structures 502 under the second isolation structure segment 116 at locations near and/or at crossroads of the plurality of pixel regions 104. The top view 500 of FIG. 5 may be taken along the line A-A′ of FIG. 6. The cross-sectional view 600 of FIG. 6 may be taken along the line A-A′ of FIG. 5.

As illustrated in the top view 500 of FIG. 5, in some embodiments, the substrate 102 may comprise the plurality of pillar structures 502 at crossroads of the plurality of pixel regions 104 under the second isolation structure segment 116. As illustrated in the cross-sectional view 600 of FIG. 6, the plurality of pillar structures 502 protrude in a direction away from the front-side surface 102f of the substrate 102. The plurality of pillar structures 502 may continuously laterally extend between directly adjacent photodetectors 106. In some embodiments, the substrate 102 may comprise the plurality of pillar structures 502 because the second diagonal distance (164 of FIG. 5) is relatively small (e.g., less than about 120 nm) and/or is less than the first diagonal distance (141 of FIG. 5). In such embodiments, a polymer used in the etch process that defines the trench in the substrate 102 may accumulate in the trench of the substrate 102 at crossroads of the plurality of pixel regions 104 where the second isolation structure segment 116 is subsequently formed. This may occur because a depth of the trench of the substrate 102 at the crossroads of the plurality of pixel regions 104 where the second isolation structure segment 116 is relatively deep and may result in an accumulation of the polymer in these deeper regions.

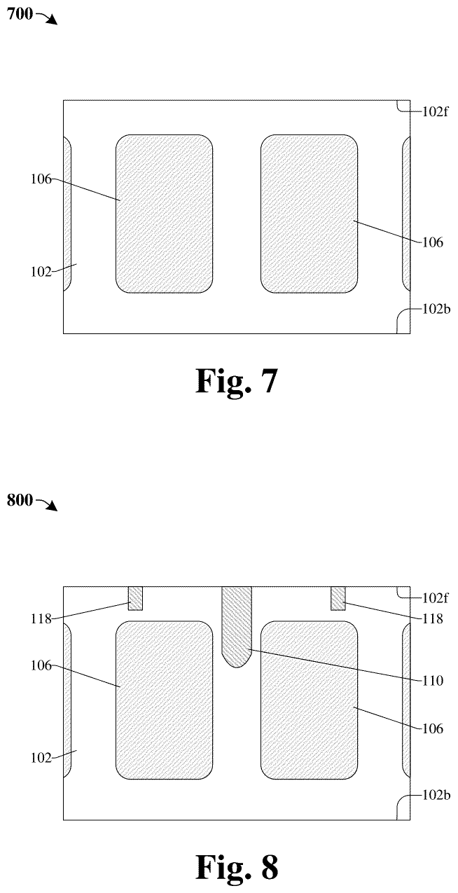

FIGS. 7-15 illustrate various views of some embodiments of a method of forming an image sensor comprising a plurality of pixel regions and an isolation structure with a layout configured to increase performance of the image sensor. Although the various views shown in FIGS. 7-15 are described with reference to the method, it will be appreciated that the structures shown in FIGS. 7-15 are not limited to the method but rather may stand alone separate of the method. Furthermore, although FIGS. 7-15 are described as a series of acts, it will be appreciated that these acts are not limited in that the order of the acts can be altered in other embodiments, and the methods discloses are also applicable to other structures. In other embodiments, some acts that are illustrated and/or described may be omitted in whole or in part.

As shown in cross-sectional view 700 of FIG. 7, a plurality of photodetectors 106 is formed in a substrate 102. The substrate 102 may, for example, be or comprise silicon, CMOS bulk, silicon-germanium, an SOI, or some other suitable semiconductor material and may have a first doping type (e.g., p-type). In some embodiments, forming the plurality of photodetectors 106 comprises: forming a masking layer (not shown) over a front-side surface 102f of the substrate 102; performing a doping process to implant dopants into the substrate 102 having a second doping type (e.g., n-type); and removing the masking layer.

As shown in cross-sectional view 800 of FIG. 8, a plurality of doped contact regions 118 and a well region 110 are formed within the substrate 102. In some embodiments, the plurality of doped contact regions 118 and the well region 110 may respectively be formed by: forming a masking layer (not shown) over the front-side surface 102f of the substrate 102; performing a doping process to implant dopants into the substrate 102 having the first doping type (e.g., p-type); and removing the masking layer. In various embodiments, the plurality of doped contact regions 118 may be formed by a doping process different from another doping process utilized to from the well region 110.

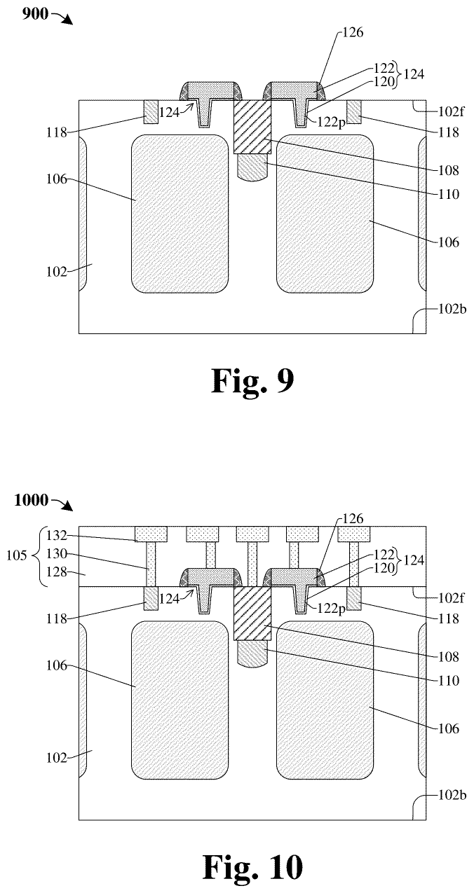

As shown in cross-sectional view 900 of FIG. 9, a plurality of transfer gate structures 124 and a floating diffusion node 108 are formed in and/or on the substrate 102. In some embodiments, forming the plurality of transfer gate structures 124 comprises: performing a first patterning process on the front-side surface 102f of the substrate 102 to form gate protrusion trenches in the substrate 102; depositing (e.g., by chemical vapor deposition (CVD), physical vapor deposition (PVD), atomic layer deposition (ALD), etc.) a gate dielectric layer 120 over the substrate 102 and lining the gate protrusion trenches; depositing (e.g., by CVD, PVD, ALD, etc.) a gate electrode 122 on the gate dielectric layer 120; and performing a second patterning process on the gate dielectric layer 120 and the gate electrode 122. The floating diffusion node 108 is formed in the substrate 102 by, for example, a doping process. The floating diffusion 108 has the second doping type (e.g., n-type) and directly overlies the well region 110. Further, a sidewall spacer 126 is formed along outer sidewalls of the gate electrode 122 and outer sidewalls of the gate dielectric layer 120.

The gate dielectric layer 120 may, for example, be or comprise silicon dioxide, aluminum oxide, tantalum oxide, hafnium oxide, some other dielectric material, or any combination of the foregoing. The gate electrode 122 may, for example, be or comprise polysilicon, tungsten, titanium nitride, aluminum, tantalum, some other conductive material, or any combination of the foregoing.

As shown in cross-sectional view 1000 of FIG. 10, an interconnect structure 105 is formed on the front-side surface 102f of the substrate 102. The interconnect structure 105 comprises a dielectric structure 128, a plurality of conductive vias 130, and a plurality of conductive wires 132. The dielectric structure 128 may, for example, be formed by one or more deposition processes, such as a CVD process, a PVD process, an ALD process, or another suitable growth or deposition process. In various embodiments, the plurality of conductive vias 130 and the plurality of conductive wires 132 may by formed by a single damascene process, a dual damascene process, or some other suitable process.

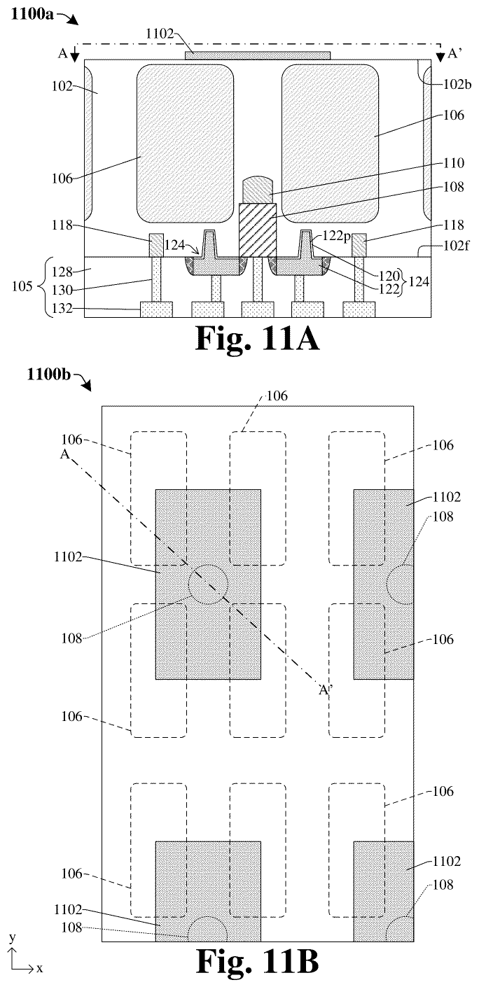

As shown in cross-sectional view 1100a of FIG. 11A and top view 1100b of FIG. 11B, the structure of FIG. 10 is flipped and a first masking layer 1102 is formed on a back-side surface 102b of the substrate 102. The cross-sectional view 1100a of FIG. 11A is taken along the line A-A′ in the top view 1100b of FIG. 11B. In some embodiments, before forming the first masking layer 1102, a thinning process (not shown) is performed into the back-side surface 102b of the substrate 102 to reduce a thickness of the substrate 102. The thinning process may, for example, be or comprise a mechanical grinding process, a chemical-mechanical planarization (CMP) process, or the like. In various embodiments, as shown in FIG. 11B, the first masking layer 1102 is formed over each floating diffusion node 108 at crossroads of the plurality of photodetectors 106. The first masking layer 1102 may, for example, be or comprise a photoresist, a dielectric material (e.g., silicon nitride, silicon dioxide, etc.), a metal (e.g., titanium, aluminum, etc.), or the like. In some embodiments, the first masking layer 1102 is formed by a photolithography process.

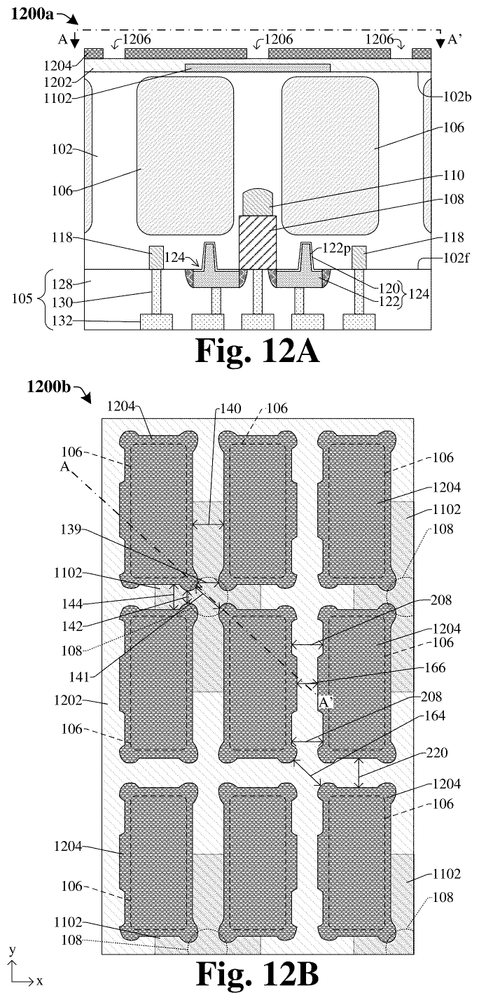

As shown in cross-sectional view 1200a of FIG. 12A and top view 1200b of FIG. 12B, a first dielectric layer 1202 is formed on the back-side surface 102b of the substrate 102 over the first masking layer 1102 and a second masking layer 1204 is formed on the first dielectric layer 1202. The cross-sectional view 1200a of FIG. 12A is taken along the line A-A′ in the top view 1200b of FIG. 12B. It will be appreciated that the first dielectric layer 1202 is at least partially transparent in the top view 1200b of FIG. 12B to show a layout of the first masking layer 1102 relatively to the second masking layer 1204.

The first dielectric layer 1202 may, for example, be or comprise silicon dioxide or some other suitable dielectric material. The first dielectric layer 1202 may, for example, be formed on the back-side surface 102b by a CVD process, a PVD process, an ALD process, or some other suitable growth or deposition process. The second masking layer 1204 may, for example, be or comprise a photoresist, a dielectric material (e.g., silicon nitride, silicon dioxide, etc.), a metal (e.g., titanium, aluminum, etc.), or the like. In some embodiments, the second masking layer 1204 is formed by a photolithography process. The second masking layer 1204 comprises sidewalls defining a plurality of openings 1206 over the first dielectric layer 1202.

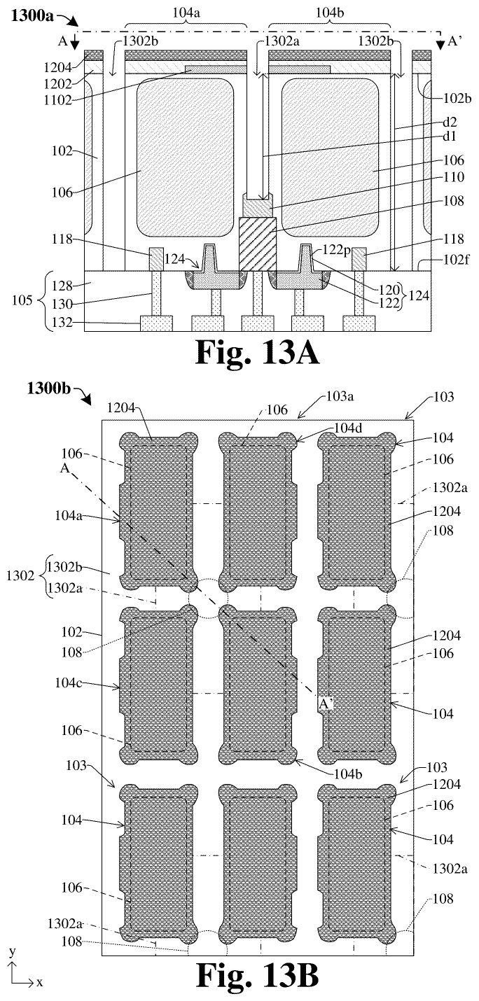

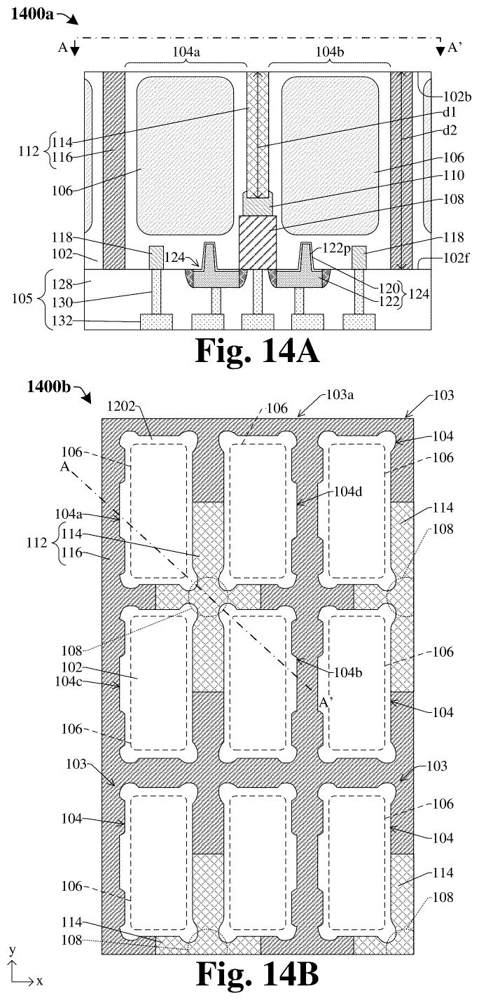

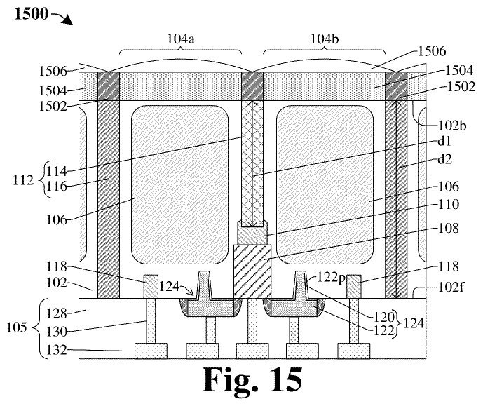

As shown in FIG. 12B, in some embodiments, the second masking layer 1204 comprises a plurality of masking segments that directly overlie a corresponding photodetector in the plurality of photodetectors 106, where each masking segment comprises a layout that corresponds to a layout of the subsequently formed and/or defined pixel regions (e.g., 103 of FIGS. 13A-13B). In various embodiments, the second masking layer 1204 is formed to have a layout such that the openings 1206 have a layout that corresponds to a layout of a subsequently formed isolation structure (e.g., 112 of FIGS. 14A-14B). For example, the second masking layer 1204 may have sidewall segments that are separated from one another by one or more distances that sidewall segments of the isolation structure (112 of FIG. 2A) are separated by as illustrated and/or described in FIG. 2A. It will be appreciated that the second masking layer 1204 may, for example, be formed with a pattern such that the openings 1206 have a layout that corresponds to the layout of the isolation structure of any one of FIGS. 1A, 3, or 5.

As shown in cross-sectional view 1300a of FIG. 13A and top view 1300b of FIG. 13B, an etching process is performed into the back-side surface 102b of the substrate 102 to form an isolation trench 1302 comprising a plurality of first trench components 1302a having a first depth d1 and a second trench component 1302b having a second depth d2. The cross-sectional view 1300a of FIG. 13A is taken along the line A-A′ in the top view 1300b of FIG. 13B. In various embodiments, the etching process forms sidewalls in the substrate 102 that define the isolation trench 1302 and defines and/or demarcates a plurality of pixel regions 104 that each comprise a corresponding photodetector 106 and are part of a plurality of pixel sensor units 103.

Portions of the first masking layer 1102 being arranged directly under portions of the openings (1206 of FIG. 12A) facilitates the first depth d1 being less than the second depth d2. In some embodiments, the substrate 102 is etched more quickly than the first masking layer 1102 during the etching process, thereby facilitating the first trench components 1302a being formed with the first depth d1 while concurrently formed the second trench component 1302b with the second depth d2. In various embodiments, an etch rate ratio of the substrate 102 and the first masking layer 1102 is within a range of about 1.5:1 to 20:1 or some other suitable value.

In some embodiments, the etching process includes performing a dry etch, a wet etch, a deep reactive ion etch, a plasma etch, some other suitable etch, or any combination of the foregoing. In various embodiments, the etching process includes: performing a first etch (e.g., a plasma dry etch) that directs one or more first etchants into the back-side surface 102b of the substrate 102 with the first and second masking layers 1102, 1204 in place and defines one or more sidewalls in the substrate 102 that define the isolation trench 1302; and performing a second etch (e.g., a wet etch) that exposes the substrate to one or more second etchants. In some embodiments, the one or more first etchants comprise chlorine-bases etchants (e.g., Cl₂, HCl, etc.), fluorine-based etchants (e.g., CF₄, CHF₃, etc.), or the like. In further embodiments, while flowing the one or more first etchants into the back-side surface 102b, one or more passivation gases may be flowed over the substrate, where the one or more passivation gases are configured to deposit a sidewall protection layer (e.g., comprising a polymer) onto sidewalls of the substrate 102 that define the isolation trench 1302 during the first etch. The one or more passivation gases may, for example, be or comprise Octafluorocyclobutane (C₄F₈), a Flourocarbon (e.g., C₄F₆, C₅F₅, etc.), some other suitable gas, or any combination of the foregoing. In various embodiments, the second etch is performed after the first etch and is configured to remove the sidewall protection layer from the sidewalls of the substrate 102. The one or more second etchants may, for example be or comprise Tetramethylammonium Hydroxide or some other suitable etchants.

In various embodiments, due to the second masking layer 1204 being formed with the pattern as illustrated and/or described in FIGS. 12A-12B, a flow of the one or more first etchants during the first etch in the first trench components 1302a is more uniform. As a result, over or under etching of the substrate in areas alighted with the floating diffusion nodes 108 across the plurality of pixel sensor units 103 is prevented or mitigated. This, in part, mitigates a formation of current leakage paths in the substrate 102 between adjacent pixel regions 104. Further, the flow of the one or more first etchants and/or the one or more passivation gases in the second trench component 1302b at crossroads of the plurality of pixel regions 104 is more uniform. Accordingly, accumulation of a material (e.g., polymer) of the sidewall protection layer at the crossroads of the plurality of pixel regions 104 in the second trench component 1302b is mitigated, thereby mitigating a formation of columnar or pillar structures in the substrate 102 at and/or near the crossroads of the plurality of pixel regions 104 in the second trench component 1302b. As a result, leakage current across the plurality of pixel regions 104 is further reduced.

A shown in cross-sectional view 1400a of FIG. 14A and top view 1400b of FIG. 14B, an isolation structure 112 is formed in the isolation trench (1302 of FIGS. 13A-13B). The isolation structure 112 comprises first isolation structure segments 114 having the first depth d1 and a second isolation structure segment 116 having the second depth d2. In some embodiments, forming the isolation structure 112 includes: depositing (e.g., by CVD, PVD, ALD, etc.) one or more trench fill materials in the isolation trench (1302 of FIGS. 13A-13B) and performing a planarization process into the one or more trench fill materials. The one or more trench fill materials may, for example, be or comprise a dielectric material (e.g., silicon dioxide, silicon carbide, silicon carbide, aluminum oxide, hafnium oxide, or some other suitable dielectric material), a metal material (e.g., aluminum, tungsten, titanium, or some other suitable metal), some other material, or any combination of the foregoing. In various embodiments, the one or more trench fill materials may include one or more liner layers (e.g., comprising silicon dioxide, aluminum oxide, hafnium oxide, etc.) and a trench fill material (e.g., a dielectric material or a metal material). In some embodiments, the planarization process may, for example, be or comprise an etch process, a CMP process, some other suitable process, or any combination of the foregoing. In various embodiments, the first isolation structure segments 114 and the second isolation structure segment 116 comprise a same material.

The second masking layer (1204 of FIGS. 12A-12B) having the layout as illustrated and/or described in FIGS. 12A-12B facilitates the isolation structure 112 having the layout as illustrated and/or described in FIG. 2A. It will be appreciated that the second masking layer (1204 of FIGS. 12A-12B) may have another layout to facilitate the isolation structure 112 having a layout as illustrated and/or described in anyone of FIGS. 1A, 3, or 5. As a result, issues (e.g., due to etch loading) during the etching process of FIGS. 13A-13B may be mitigated, thereby decreasing current leakage across the plurality of pixel sensor units 103 and increasing a dynamic range of the image sensor.

As illustrated in cross-sectional view 1500 of FIG. 15, a grid structure 1502, a plurality of light filters 1504, and a plurality of micro-lenses 1506 are formed over the back-side surface 102b of the substrate 102. Forming the grid structure 1502 may include depositing a grid material over the substrate 102 and subsequently patterning the grid material. Forming the plurality of light filters 1504 may include depositing and patterning respective light filter layers. Further, forming the plurality of micro-lenses 1506 may include depositing a micro-lens material over the plurality of light filters 1504 and patterning the micro-lens material.

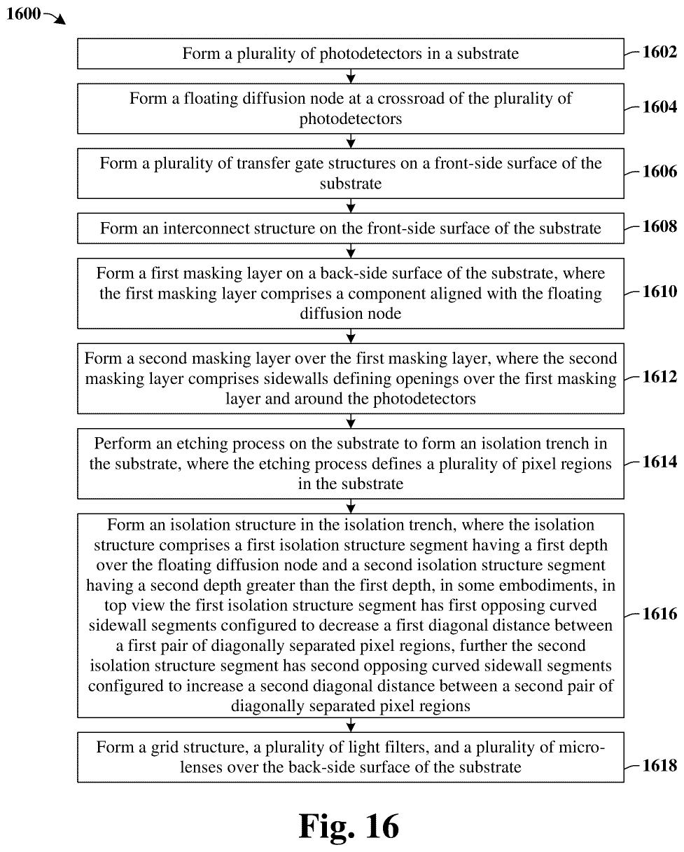

FIG. 16 illustrates a flowchart of some embodiments of a method 1600 for forming an image sensor comprising a plurality of pixel regions and an isolation structure with a layout configured to increase performance of the image sensor. Although the method 1600 is illustrated and/or described as a series of acts or events, it will be appreciated that the method 1600 is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 1602, a plurality of photodetectors is formed in a substrate. FIG. 7 illustrates a cross-sectional view 700 corresponding to some embodiments of act 1602.

At act 1604, a floating diffusion node is formed at a crossroad of the plurality of photodetectors. FIG. 9 illustrates a cross-sectional view 900 corresponding to some embodiments of act 1604.

At act 1606, a plurality of transfer gate structures is formed on a front-side surface of the substrate. FIG. 9 illustrates a cross-sectional view 900 corresponding to some embodiments of act 1606.

At act 1608, an interconnect structure is formed on the front-side surface of the substrate. FIG. 10 illustrates a cross-sectional view 1000 corresponding to some embodiments of act 1608.

At act 1610, a first masking layer is formed on a back-side surface of the substrate. The first masking layer comprises a component aligned with the floating diffusion node. FIGS. 11A and 11B illustrate a cross-sectional view 1100a and a top view 1100b corresponding to some embodiments of act 1610.

At act 1612, a second masking layer is formed over the first masking layer. The second masking layer comprises sidewalls defining openings over the first masking layer and around the photodetectors. FIGS. 12A and 12B illustrate a cross-sectional view 1200a and a top view 1200b corresponding to some embodiments of act 1612.

At act 1614, an etching process is performed on the substrate to form an isolation trench in the substrate, where the etching process defines a plurality of pixel regions in the substrate. FIGS. 13A and 13B illustrate a cross-sectional view 1300a and a top view 1300b corresponding to some embodiments of act 1614.

At act 1616, an isolation structure is formed in the isolation trench. The isolation structure comprises a first isolation structure segment having a first depth over the floating diffusion node and a second isolation structure segment having a second depth greater than the first depth. In some embodiments, in top view the first isolation structure segment has first opposing curved sidewall segments configured to decrease a first diagonal distance between a first pair of diagonally separated pixel regions. Further, the second isolation structure segment has second opposing curved sidewalls segments configured to increase a second diagonal distance between a second pair of diagonally separated pixel regions. FIGS. 14A and 14B illustrate a cross-sectional view 1400a and a top view 1400b corresponding to some embodiments of act 1616.

At act 1618, a grid structure, a plurality of light filters, and a plurality of micro-lenses are formed over the back-side surface of the substrate. FIG. 16 illustrates a cross-sectional view 1500 corresponding to some embodiments of act 1618.

Accordingly, in some embodiments, the present disclosure relates to an image sensor comprising an isolation structure arranged between a plurality of pixel regions disposed in a substrate. In top view, the isolation structure has first opposing straight sidewall segments separated by a first distance and connected to first opposing curved sidewall segments over a floating diffusion node, wherein a second distance between the first opposing curved sidewall segments is less than the first distance.

In some embodiments, the present application provides an integrated chip (IC). The IC includes a first pixel region comprising a first photodetector in a substrate; a second pixel region comprising a second photodetector in the substrate and adjacent to the first pixel region; and an isolation structure in the substrate and comprising a first isolation structure element between the first and second pixel regions, wherein in top view the first isolation structure element has a first pair of opposing straight sidewall segments and a first pair of opposing curved sidewall segments adjacent to the first pair of opposing straight sidewall segments, wherein a first distance between the first pair of opposing straight sidewall segments is greater than a second distance between the first pair of opposing curved sidewall segments. In an embodiment, the first pair of opposing straight sidewall segments and the first pair of opposing curved sidewall segments are disposed directly between the first pixel region and the second pixel region. In an embodiment, the first pair of opposing straight sidewall segments is arranged on a first side of the first pixel region, wherein the first isolation structure element comprises a second pair of opposing straight sidewall segments arranged on a second side of the first pixel region, wherein a third distance between the second pair of opposing straight sidewall segments is greater than the second distance. In an embodiment, the isolation structure comprises a second isolation structure element in the substrate and disposed at least partially around the first and second pixel regions, wherein the first isolation structure element has a first depth and the second isolation structure element has a second depth greater than the first depth. In an embodiment, the second isolation structure element comprises a second pair of opposing straight sidewall segments arranged laterally between the first pixel region and the second pixel region, wherein a third distance between the second pair of opposing straight sidewall segments is less than the first distance. In an embodiment, the first pair of opposing straight sidewall segments and the second pair of opposing straight sidewall segments are respectively elongated in a first direction. In an embodiment, the IC further includes a third pixel region comprising a third photodetector in the substrate and laterally adjacent to the second pixel region; wherein the second isolation structure element comprises a second pair of opposing curved sidewall segments spaced between the second pixel region and the third pixel region, wherein a third distance between the second pair of opposing curved sidewall segments is greater than the second distance. In an embodiment, the second isolation structure element comprises a second pair of opposing straight sidewall segments adjacent to the second pair of opposing curved sidewall segments, wherein a fourth distance between the second pair of opposing straight sidewall segments is greater than the third distance.

In some embodiments, the present application provides an IC. The IC includes a first pixel region in a substrate; and a second pixel region in the substrate and adjacent to the first pixel region. In top view, the substrate comprises a first rounded sidewall segment, a first elongated sidewall segment connected to the first rounded sidewall segment, a second rounded sidewall segment adjacent to the first rounded sidewall segment, and a second elongated sidewall segment connected to the second rounded sidewall segment and adjacent to the first elongated sidewall segment, wherein the first rounded sidewall segment and the first elongated sidewall segment define a portion of an outer perimeter of the first pixel region and the second rounded sidewall segment and the second elongated sidewall segment define a portion of an outer perimeter of the second pixel region, wherein a first lateral distance between the first and second elongated sidewall segments is greater than a second lateral distance between the first and second rounded sidewall segments. In an embodiment, the IC further includes a floating diffusion node in the substrate and spaced laterally between the first pixel region and the second pixel region, wherein the first and second rounded sidewall segments are at least partially laterally aligned with the floating diffusion node and the first and second elongated sidewall segments are laterally offset from the floating diffusion node. In an embodiment, the IC further includes a third pixel region in the substrate and diagonally opposite the first pixel region, wherein in top view a part of the substrate comprises a third rounded sidewall segment defining a first corner of the third pixel region and a fourth rounded sidewall segment defining a second corner of the third pixel region, wherein the third rounded sidewall segment is offset from the first rounded sidewall segment by a first diagonal distance; and a fourth pixel region in the substrate and diagonally opposite the third pixel region, wherein in top view the substrate comprises a fifth rounded sidewall segment defining a first corner of the fourth pixel region, wherein the first corner of the fourth pixel region is adjacent to the second corner of the third pixel region, wherein the fourth rounded sidewall segment is offset from the fifth rounded sidewall segment by a second diagonal distance greater than the first diagonal distance. In an embodiment, a first shape of the third rounded sidewall segment is different from a shape of the fourth rounded sidewall segment. In an embodiment, the IC further includes a third pixel region in the substrate and adjacent to the second pixel region; and an isolation structure in the substrate and laterally wrapped around the first, second, and third pixel regions, wherein the isolation structure comprises a first isolation component spanning a first side of the second pixel region and spaced between the second pixel region and the third pixel region, wherein a width of the first isolation component discretely changes at least four times along the first side of the second pixel region. In an embodiment, the second rounded sidewall segment and the second elongated sidewall segment of the part of the substrate are disposed on a second side of the second pixel region opposite the first side, wherein the first lateral distance is greater than the width of the first isolation component at a middle of a length of the first isolation component. In an embodiment, the isolation structure has a first depth adjacent to the first and second rounded sidewall segments of the substrate and the first isolation component has a second depth greater than the first depth.

In some embodiments, the present application provides a method for forming an IC. The method includes forming a plurality of photodetectors in a substrate, wherein the substrate has a first surface opposite a second surface; forming a floating diffusion node at a first crossroad of a first subset of the plurality of photodetectors; performing an etching process on the substrate to form an isolation trench defined by sidewalls of the substrate extending into the second surface of the substrate, wherein the isolation trench comprises a first trench segment arranged at the first crossroad and aligned with the floating diffusion node and a second trench segment offset from the first trench segment and around the plurality of photodetectors, wherein the first trench segment has a first depth less than a second depth of the second trench segment; and forming an isolation structure in the isolation trench, wherein the isolation structure comprises a first isolation structure segment in the first trench segment and a second isolation structure segment in the second trench segment, wherein the first isolation structure segment comprises a first pair of opposing curved sidewall segments over the floating diffusion node, wherein the second isolation structure segment comprises a second pair of opposing curved sidewall segments arranged at a second crossroad of a second subset of the plurality of photodetectors, wherein a first distance between the first pair of opposing curved sidewall segments is less than a second distance between the second pair of opposing curved sidewall segments. In an embodiment, the method further includes forming a first masking layer on the second surface of the substrate, wherein the first masking layer is aligned with the floating diffusion node and is laterally offset from the second crossroad; and forming a second masking layer over the first masking layer, wherein the second masking layer comprises sidewalls defining an opening directly over the first masking layer, wherein the etching process is performed while the first and second masking layers are disposed on the substrate. In an embodiment, the first isolation structure segment comprises a first pair of opposing straight sidewall segments connected to the first pair of opposing curved sidewall segments, wherein a third distance between the first pair of opposing straight sidewall segments is greater than the first distance. In an embodiment, the second isolation structure segment comprises a first pair of opposing straight sidewall segments adjacent to the second pair of opposing curved sidewall and a second pair of opposing straight sidewall segments adjacent to the first pair of opposing straight sidewall segments, wherein a third distance between the first pair of opposing straight sidewall segments is greater than a fourth distance between the second pair of opposing straight sidewall segments. In an embodiment, the third distance is greater than the second distance.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip (IC), comprising:
a first pixel region comprising a first photodetector in a substrate;
a second pixel region comprising a second photodetector in the substrate and adjacent to the first pixel region; and
an isolation structure in the substrate and comprising a first isolation structure element between the first and second pixel regions, wherein in top view the first isolation structure element has a first pair of opposing straight sidewall segments and a first pair of opposing curved sidewall segments adjacent to the first pair of opposing straight sidewall segments, wherein a first distance between the first pair of opposing straight sidewall segments is greater than a second distance between the first pair of opposing curved sidewall segments.

2. The IC of claim 1, wherein the first pair of opposing straight sidewall segments and the first pair of opposing curved sidewall segments are disposed directly between the first pixel region and the second pixel region.

3. The IC of claim 1, wherein the first pair of opposing straight sidewall segments is arranged on a first side of the first pixel region, wherein the first isolation structure element comprises a second pair of opposing straight sidewall segments arranged on a second side of the first pixel region, wherein a third distance between the second pair of opposing straight sidewall segments is greater than the second distance.

4. The IC of claim 1, wherein the isolation structure comprises a second isolation structure element in the substrate and disposed at least partially around the first and second pixel regions, wherein the first isolation structure element has a first depth and the second isolation structure element has a second depth greater than the first depth.

5. The IC of claim 4, wherein the second isolation structure element comprises a second pair of opposing straight sidewall segments arranged laterally between the first pixel region and the second pixel region, wherein a third distance between the second pair of opposing straight sidewall segments is less than the first distance.

6. The IC of claim 5, wherein the first pair of opposing straight sidewall segments and the second pair of opposing straight sidewall segments are respectively elongated in a first direction.

7. The IC of claim 4, further comprising:
a third pixel region comprising a third photodetector in the substrate and laterally adjacent to the second pixel region; and
wherein the second isolation structure element comprises a second pair of opposing curved sidewall segments spaced between the second pixel region and the third pixel region, wherein a third distance between the second pair of opposing curved sidewall segments is greater than the second distance.

8. The IC of claim 7, wherein the second isolation structure element comprises a second pair of opposing straight sidewall segments adjacent to the second pair of opposing curved sidewall segments, wherein a fourth distance between the second pair of opposing straight sidewall segments is greater than the third distance.

9. An integrated chip (IC), comprising:
a first pixel region in a substrate; and
a second pixel region in the substrate and adjacent to the first pixel region;
wherein in top view, a part of the substrate comprises a first rounded sidewall segment, a first elongated sidewall segment connected to the first rounded sidewall segment, a second rounded sidewall segment adjacent to the first rounded sidewall segment, and a second elongated sidewall segment connected to the second rounded sidewall segment and adjacent to the first elongated sidewall segment, wherein the first rounded sidewall segment and the first elongated sidewall segment define a portion of an outer perimeter of the first pixel region and the second rounded sidewall segment and the second elongated sidewall segment define a portion of an outer perimeter of the second pixel region, wherein a first lateral distance between the first and second elongated sidewall segments is greater than a second lateral distance between the first and second rounded sidewall segments.

10. The IC of claim 9, further comprising:
a floating diffusion node in the substrate and spaced laterally between the first pixel region and the second pixel region, wherein the first and second rounded sidewall segments are at least partially laterally aligned with the floating diffusion node and the first and second elongated sidewall segments are laterally offset from the floating diffusion node.

11. The IC of claim 9, further comprising:
a third pixel region in the substrate and diagonally opposite the first pixel region, wherein in top view the substrate comprises a third rounded sidewall segment defining a first corner of the third pixel region and a fourth rounded sidewall segment defining a second corner of the third pixel region, wherein the third rounded sidewall segment is offset from the first rounded sidewall segment by a first diagonal distance; and
a fourth pixel region in the substrate and diagonally opposite the third pixel region, wherein in top view the substrate comprises a fifth rounded sidewall segment defining a first corner of the fourth pixel region, wherein the first corner of the fourth pixel region is adjacent to the second corner of the third pixel region, wherein the fourth rounded sidewall segment is offset from the fifth rounded sidewall segment by a second diagonal distance greater than the first diagonal distance.

12. The IC of claim 11, wherein a first shape of the third rounded sidewall segment is different from a shape of the fourth rounded sidewall segment.

13. The IC of claim 9, further comprising:
a third pixel region in the substrate and adjacent to the second pixel region; and
an isolation structure in the substrate and laterally wrapped around the first, second, and third pixel regions, wherein the isolation structure comprises a first isolation component spanning a first side of the second pixel region and spaced between the second pixel region and the third pixel region, wherein a width of the first isolation component discretely changes at least four times along the first side of the second pixel region.

14. The IC of claim 13, wherein the second rounded sidewall segment and the second elongated sidewall segment of the part of the substrate are disposed on a second side of the second pixel region opposite the first side, wherein the first lateral distance is greater than the width of the first isolation component at a middle of a length of the first isolation component.

15. The IC of claim 13, wherein the isolation structure has a first depth adjacent to the first and second rounded sidewall segments of the substrate and the first isolation component has a second depth greater than the first depth.

16. A method for forming an integrated chip (IC), comprising:
forming a plurality of photodetectors in a substrate, wherein the substrate has a first surface opposite a second surface;
forming a floating diffusion node at a first crossroad of a first subset of the plurality of photodetectors;
performing an etching process on the substrate to form an isolation trench defined by sidewalls of the substrate extending into the second surface of the substrate, wherein the isolation trench comprises a first trench segment arranged at the first crossroad and aligned with the floating diffusion node and a second trench segment offset from the first trench segment and around the plurality of photodetectors, wherein the first trench segment has a first depth less than a second depth of the second trench segment; and
forming an isolation structure in the isolation trench, wherein the isolation structure comprises a first isolation structure segment in the first trench segment and a second isolation structure segment in the second trench segment, wherein the first isolation structure segment comprises a first pair of opposing curved sidewall segments over the floating diffusion node, wherein the second isolation structure segment comprises a second pair of opposing curved sidewall segments arranged at a second crossroad of a second subset of the plurality of photodetectors, wherein a first distance between the first pair of opposing curved sidewall segments is less than a second distance between the second pair of opposing curved sidewall segments.

17. The method of claim 16, further comprising:
forming a first masking layer on the second surface of the substrate, wherein the first masking layer is aligned with the floating diffusion node and is laterally offset from the second crossroad; and
forming a second masking layer over the first masking layer, wherein the second masking layer comprises sidewalls defining an opening directly over the first masking layer, wherein the etching process is performed while the first and second masking layers are disposed on the substrate.

18. The method of claim 16, wherein the first isolation structure segment comprises a first pair of opposing straight sidewall segments connected to the first pair of opposing curved sidewall segments, wherein a third distance between the first pair of opposing straight sidewall segments is greater than the first distance.

19. The method of claim 16, wherein the second isolation structure segment comprises a first pair of opposing straight sidewall segments adjacent to the second pair of opposing curved sidewall and a second pair of opposing straight sidewall segments adjacent to the first pair of opposing straight sidewall segments, wherein a third distance between the first pair of opposing straight sidewall segments is greater than a fourth distance between the second pair of opposing straight sidewall segments.

20. The method of claim 19, wherein the third distance is greater than the second distance.
